(19) United States
(12) Patent Application Publication
(10) Pub. No.: US 2006/0198570 A1
(43) Pub. Date: Sep. 7, 2006

(54) Hybrid module and production method for same, and hybrid circuit device

(76) Inventors: Tsuyoshi Ogawa, Kanagawa (JP); Hirokazu Nakayama, Kanagawa (JP)

Correspondence Address: ROBERT J. DEPKE;LEWIS T. STEADMAN, ROCKEY, DEPKE, LYONS AND KITZINGER, LLC, SUITE 5450 SEARS TOWER, CHICAGO, IL, 60606-6306, US

(21) Appl. No.: 11/340,025

(22) Filed: Jan. 26, 2006

(30) Foreign Application Priority Data
Feb. 28, 2005 (JP) JP2005-054842

(51) Int. Cl. G02B 6/12

(52) U.S. Cl. 385/14

(57) ABSTRACT

Components can be mounted with an improved accuracy and efficiency, thereby realizing a thin hybrid module in which the components are mounted with a high density. The present invention provides a hybrid module including a silicon substrate having formed therein a plurality of component mounting concavities open to one of main sides of the silicon substrate, a plurality of components inserted in the component mounting concavities, respectively, with their input/output-formed sides being exposed to outside through the openings of the component mounting concavities and buried in the silicon substrate with their perimeters except for at least their input/output-formed sides being fixed by adhesive layers formed in the component mounting concavities, and a wiring layer formed on the main side of the silicon substrate to cover the components and which has a wiring pattern provided on an insulative resin layer included in the wiring layer and which is connected to an input/output provided on the input/output-formed side of each of the components.

### CROSS REFERENCES TO RELATED APPLICATIONS

The present invention contains subject matter related to Japanese Patent Application JP 2005-054842 filed in the Japanese Patent Office on Feb. 28, 2005, the entire content of which is incorporated herein by reference.

### BACKGROUND OF THE INVENTION

1. Field of the Invention

The present invention relates to a hybrid module having a plurality of components such as chips, IC (integrated circuit) elements or optical elements installed on a silicon substrate and including a wiring layer and a production method for the hybrid module, and a hybrid circuit device having the hybrid module installed thereon.

2. Description of the Related Art

For example, various electronic devices such as a personal computer, mobile phone, video recorder or audio device use various semiconductor circuit elements and electronic components such as IC (integrated circuit) elements, LSI (large-scale integration) elements or memory elements. The electronic device is equipped with a so-called module hybridized by installing, on a base substrate having a wiring layer formed thereon, the above semiconductor circuit elements and electronic components, which perform the same function.

As the electronic devices have been required to have a smaller design and more functions or a higher functionality, the hybrid module is designed for installing correspondingly more components with a higher density as well as to be smaller and more lightweight. For example, the Japanese Patent Application Laid Open No. 7134 of 1995 (patent document 1) or 2000-106417 (patent document 2) discloses a hybrid module having many components so sealed in a resin base thereof that their input/output-formed sides are formed flush with each other, and a wiring layer formed on the main side of the resin base. To attain a thinner design and higher packaging density of such a hybrid module, it has been tried to install components and mount also other components on the already installed components via the wiring layer.

On the other hand, in the electronic devices or the like, signal transmission between components installed in a circuit board is generally effected according to a wiring pattern formed in the wiring layer. The electronic devices are required to operate at a higher speed. In the transmission of electrical signals according to the wiring pattern, however, it is extremely difficult to attain the higher speed of operation because of the limited reduction in line thickness of the wiring pattern, delay of signal transmission due to CR (capacitance-resistance) time constant arising in the wiring pattern, EMI (electromagnetic interference) or EMC (electromagnetic compatibility), crosstalk between the wiring patterns or the like.

For solving the problems of the conventional electrical signal transmission structure to implement an electronic device capable of operating at a higher speed and having more functions or a higher functionality, it has been studied to adopt an optical signal transmission structure including optical components such as an optical signal channel (optical path), optical interconnection, etc. The optical signal transmission structure is suitable for signal transmission over a relatively short distance between devices, circuit boards used in each device or components mounted on each board. The optical signal transmission structure makes it possible to transmit an optical signal at a higher speed and in a larger volume on an optical signal transmission channel formed on a wiring board having components mounted thereon. A hybrid module having optical elements formed in combination therein is disclosed in the Japanese Patent Application Laid Open No. 2004-193221 (patent document 3).

### SUMMARY OF THE INVENTION

The hybrid module disclosed in the above-mentioned patent document 1 or 2 is formed by mounting a plurality of components such as semiconductor chips, functional devices, etc. side by side on a base sheet supported at the base thereof and molding a resin into a substrate body on the base sheet to seal the mounted components. In this hybrid module, contact pads of the mounted components are laid generally flush with each other so that the mounted components can collectively be connected to the circuit board or the like, and the substrate body is polished to the profile of a mounted component having the largest outside dimensions so that the hybrid module as a whole can be reduced in thickness.

In such a hybrid module, however, the resin-molded substrate body sealing the mounted components will incur a large dimensional change because it shrinks as the resin is cured. Thus, the substrate body will largely be warped or otherwise deformed, resulting in misalignment of connecting pads of the components with corresponding mounting lands at the circuit board and in disconnection between the component and land. Thus, the components cannot be mounted with a high accuracy. Also, cracking in the perimeter of each component, caused by a thermal stress, leads to a reduced strength of mounting and penetration of water, which will further cause internal short-circuit and rusting. Thus, the conventional hybrid module is less reliable.

On the other hand, the hybrid module having the above-mentioned optical signal transmission structure can operate at a higher speed, have more functions and a higher functionality, and is also more advantageous in other respects. In the hybrid module, an electrical signal supplied from and to LSI elements designed to operate at a higher speed and have a larger capacity is converted into an optical signal by optical elements such as semiconductor laser and light-emitting diode or photodetector. Therefore, there is also available a hybrid module having a combination of an electrical signal transmission structure and optical signal transmission structure, that is, a hybrid module addressed to both electrical and optical signals.

In the hybrid module for both electrical and optical signals, as the optical signal is transmitted at a high speed through the optical signal transmission structure, it is very important to reduce the parasitic capacitance by decreasing the CR time constant-caused delay of electrical signal transmission through the electrical signal transmission structure, EMI noise, EMC or the like. Also, in the electrical/optical signal-oriented hybrid module, the optical components generate heat when an electrical signal is converted into an optical signal and the heat will possibly have an influence on the performance of the electrical components provided in combination with the optical components.

Therefore, of the electrical/optical signal-oriented hybrid module, the optical components and optical signal transmission channel are normally mounted on the main side of the wiring layer, circuit board, etc. in a separate process from that for the electrical components. In the electrical/optical signal-oriented hybrid module, however, handling the electrical and optical components in separate processes, respectively, leads to an increased complexity and lower efficiency of the mounting process and also a lower yield of the mounting process. Also in the electrical/optical signal-oriented hybrid module, such an electrical wiring pattern is required which can connect the electrical and optical components to each other by mounting the electrical and optical components separately from each other, and the capacity of connection will make it difficult to reduce the parasitic capacitance.

It is therefore desirable to overcome the above-mentioned drawbacks of the related art by providing a thin, highly reliable hybrid module in which multiple components can be mounted with an improved accuracy and efficiency, and a production method for the hybrid module. Also, it is desirable to provide a small, multi- and high-functional, highly reliable hybrid circuit device including a thin hybrid module in which multiple components are mounted with a high density.

According to the present invention, there is provided a hybrid module including a silicon substrate having formed therein a plurality of component mounting concavities open to one of main sides of the silicon substrate, a plurality of components different in outside dimensions and the like from each other and which are inserted in the component mounting concavities, respectively, and fixed by adhesive resin layers, respectively, and a wiring layer formed on the main side of the silicon substrate. In the hybrid module, the components are inserted in the component mounting concavities with their respective sides each having an input/output formed thereon being exposed to outside through the openings of the component mounting concavities, fixed at the perimeters thereof except for at least the input/output-formed sides by adhesive resin layers formed by curing an adhesive resin filled in the component mounting concavities, and thus mounted being buried in the silicon substrate. In the hybrid module, the wiring layer includes the insulative resin layer and a wiring pattern connected to the input/output of each of the components, and it is formed on the main side of the silicon substrate and the input/output-formed sides of the components, which are laid generally flush with the main side.

In the above hybrid module, use of the silicon substrate as a base substrate permits to form high-precision component mounting concavities and wiring layer relatively easily and leads to almost no heat- or otherwise-caused change in dimensions and shape. Since the components can thus be positioned accurately and mounted being positively held connected with the wiring layer and the like, the hybrid module is improved in reliability. Since the silicon substrate in the hybrid module has a relatively large area and functions also as a ground for the components and wiring layer and a good heat radiator, the hybrid module can operate stably. Since the components different in outside dimensions from each other are mounted being buried in the silicon substrate with their input/output-formed sides being laid flush with each other, the hybrid module can be formed smaller and thinner, the components and wiring layer can be connected over a possibly shortest distance to each other to reduce the parasitic capacitance, and thus the high-density packaging provides a multi- and high-functional hybrid module.

According to the present invention, there is also provided a hybrid module producing method including the steps of forming, in a silicon substrate, a plurality of component mounting concavities open to one of main sides of the silicon substrate, mounting a plurality of components different in outside dimensions and the like from each other in a buried state into the component mounting concavities, respectively, and forming a wiring layer over the main side of the silicon substrate to cover the components, to thereby produce a hybrid module in which the components are inserted in the component mounting concavities, respectively, formed in one of main sides of the silicon substrate, buried being fixed by adhesive resin layers filled in the component mounting concavities and a wiring layer is formed over the main side. In the hybrid module producing method, the component mounting step further includes the steps of filling a predetermined amount of tack-free adhesive resin into each of the component mounting concavities, inserting the plurality of components into corresponding component mounting concavities with their respective input/output-formed sides being exposed to outside through the openings of the component mounting concavities, pressing and holding each component with the input/output-formed sides of the latter being laid generally flush with each other, and fixing each of the components by curing the adhesive resin with the component being held pressed to form an adhesive resin layer in the component mounting concavity and burying the component in the silicone substrate with the component being fixed by the adhesive resin layer. Also, in the hybrid module producing method, the wiring layer forming step further includes the steps of forming an insulating layer over the main side of the silicon substrate and the input/output-formed sides of the components, which are laid generally flush with the main side, and forming, on the insulating layer, a wiring pattern for connection to the input/output of each component.

In the hybrid module producing method, a plurality of component mounting concavities is formed efficiently in the silicon substrate by etching or with a similar technique, and components are inserted into the component mounting concavities filled with the tack-free adhesive resin. In the hybrid module producing method, the adhesive resin is cured with the components being pressed for their input/output-formed sides thereof to be laid generally flush with the main side of the silicon substrate. In the hybrid module producing method, a silicon substrate incurring little heat-caused change in shape and state is used as a base substrate to enable the components to be buried being positioned accurately in the component mounting concavities.

Therefore, the above hybrid module producing method permits to produce a hybrid module improved in reliability because the connection between the components, wiring layer, etc. can positively be maintained with prevention of disconnection. In the hybrid module produced by the method according to the present invention, the silicon substrate having a relatively large area functions as a ground for the components and wiring layer and also serves as a good heat radiator. Thus, the hybrid module can operate stably. Also, since the components are mounted being buried in the silicon substrate, so the hybrid module produced by the method according to the present invention is smaller and thinner, the components and wiring layer are connected over a possibly shortest distance between them to reduce the parasitic capacitance. Also, since a high density of mounting the components can be attained by the method according to the present invention, the hybrid module thus produced has more functions and a higher functionality.

According to the present invention, there is also provided a hybrid circuit device including a base substrate having formed on an insulating substrate thereof a base wiring layer formed from an insulating layer and a single- or multi-layer wiring pattern, and a hybrid module mounted on the base wiring layer of the base substrate. In the hybrid circuit device, the hybrid module includes a silicon substrate having formed therein a plurality of component mounting concavities open to one of main sides of the silicon substrate, a plurality of components which are inserted in the component mounting concavities, respectively, and fixed by adhesive resin layers, respectively, and a wiring layer formed on the main side of the silicon substrate. In the hybrid module included in the hybrid circuit device, the components are inserted in the component mounting concavities with their respective sides each having an input/output formed thereon being exposed to outside through the openings of the component mounting concavities, fixed at the perimeters thereof except for at least the input/output-formed sides by adhesive resin layers formed by curing an adhesive resin filled in the component mounting concavities, and thus mounted being buried in the silicon substrate. In the hybrid module of the hybrid circuit device, the wiring layer includes the insulative resin layer and a wiring pattern connected to the input/output of each of the components, and it is formed on the main side of the silicon substrate and the input/output-formed sides of the components, which are laid generally flush with the main side.

On the above hybrid circuit device, there is mounted being accurately positioned the hybrid module in which use of the silicon substrate as the base substrate permits to form high-precision component mounting concavities and a wiring layer relatively easily in the silicon substrate and leads to almost no heat- or otherwise-caused change in dimensions and shape of the components. Thus, disconnection and cracking are inhibited in the connection between the hybrid module and base substrate, and the hybrid circuit device is improved in reliability. Also on the hybrid circuit device, since on the base substrate, there is mounted the hybrid module in which the components are mounted being buried in the silicon substrate so that the hybrid module is smaller and thinner and the components and wiring layer are connected over a possibly shortest distance to each other to reduce the parasitic capacitance, so the high-density packaging provides a multi- and high-functional hybrid circuit device. In the hybrid circuit device, the hybrid module can be supplied with a high-regulation power with a power unit and ground, each having a sufficiently large area, being provided on the wiring layer of the base substrate, for example.

According to the present invention, the hybrid module is provided in which the components are inserted in the component mounting concavities formed in the silicon substrate with input/output-formed sides thereof being laid generally flush with each other and buried being fixed by the adhesive resin layer and the wiring layer for electrical connection with the components is formed on the main side of the silicon substrate. Therefore, according to the present invention, the hybrid module can be formed smaller and thinner and the components and wiring layer be connected over a possibly shortest distance to each other to reduce the parasitic capacitance. Thus, mounting the components with a higher density permits to provide a multi- and high-functional hybrid module. According to the present invention, since the silicon substrate incurring almost no change in dimension and shape due to heat is used as the base substrate, the components can be mounted being positioned with a high accuracy and disconnection be inhibited, whereby a high-precision hybrid module can be provided. According to the present invention, since the silicon substrate having a relatively large area functions also as a ground for the components and wiring layer and a good heat radiator, the hybrid module can operate stably with a high reliability.

According to the present invention, the hybrid circuit device has mounted on the base wiring layer of the base substrate thereof the hybrid module in which the components are inserted in the component mounting concavities formed in the silicon substrate with input/output-formed sides thereof being laid generally flush with each other and buried being fixed by the adhesive resin layer and the wiring layer for electrical connection with the components is formed on the main side of the silicon substrate. Therefore, according to the present invention, since the hybrid module having the components mounted being accurately positioned on the silicon substrate is mounted on the base substrate of the hybrid circuit device, the latter can be formed smaller and thinner and the high-density packaging provides a multi- and high-functional hybrid circuit device. In the hybrid circuit device, the hybrid module can be supplied with a high-regulation power with a power unit and ground, each having a sufficiently large area, being provided on the wiring layer of the base substrate, for example.

### BRIEF DESCRIPTION OF THE DRAWINGS

FIG. 1 is a sectional view of a first embodiment of the hybrid module according to the present invention;

FIG. 2 is also a sectional view of a first embodiment of the hybrid circuit device having two hybrid modules mounted thereon according to the present invention;

FIG. 3 shows a process of producing the hybrid module, showing a silicon etching film formed by patterning over the main side of a silicon substrate;

FIG. 4 shows the silicon substrate having component mounting concavities formed therein;

FIG. 5 shows the silicon substrate having the silicon etching film removed therefrom;

FIG. 6 shows the component mounting concavities having an insulating layer formed thereon;

FIG. 7 shows the component mounting concavities having a conductive layer formed thereon;

FIG. 8 shows the component mounting concavities having an adhesive resin filled therein;

FIG. 9 shows a component being sucked by a mounting device;

FIG. 10 shows the component mounting concavities in which the component is being pressed;

FIG. 11 shows the component mounting concavities in which the component is fixed by the cured adhesive resin;

FIG. 12 shows the component mounting concavities in which components are mounted being buried;

FIG. 13 shows a first insulating layer and first viahole formed on the main side of the silicon substrate;

FIG. 14 shows the first insulating layer having a second wiring pattern formed thereon;

FIG. 15 shows a second insulating layer and second viahole formed on the second wiring pattern;

FIG. 16 is a sectional view of a second embodiment of the hybrid module according to the present invention; and

FIG. 17 is also a sectional view of a second embodiment of the hybrid circuit device according to the present invention.

### DETAILED DESCRIPTION OF THE PREFERRED EMBODIMENTS

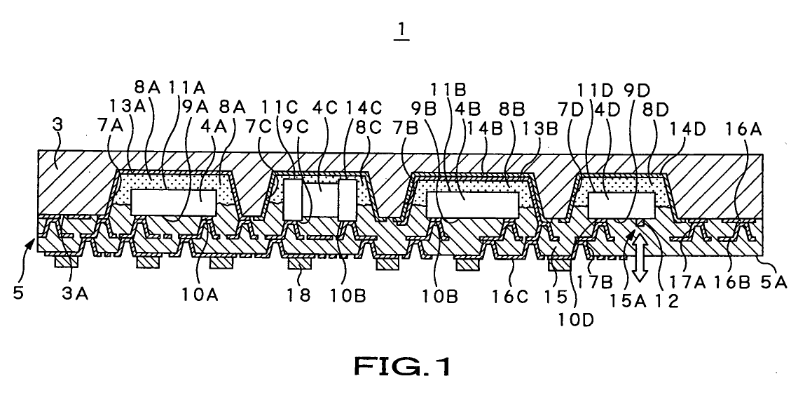

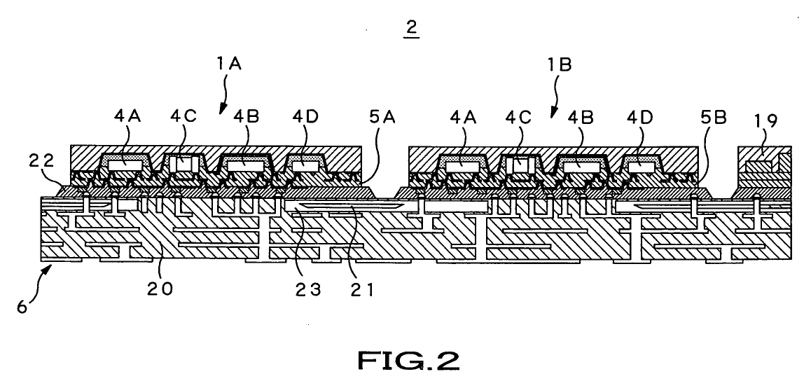

The present invention will be described in detail below concerning the embodiments thereof with reference to the accompanying drawings. FIG. 1 is a sectional view of the first embodiment of the hybrid module according to the present invention. The hybrid module is generally indicated with a reference numeral 1. As shown, the hybrid module 1 includes a silicon substrate 3, a plurality of components 4 and a wiring layer 5. FIG. 2 is a sectional view of the first embodiment of the hybrid circuit device according to the present invention. The hybrid circuit device is generally indicated with a reference numeral 2. As shown, the hybrid circuit device 2 includes two hybrid modules 1A and 2A mounted on a base substrate 6. The hybrid circuit device 2 is used in, for example, a personal computer, mobile phone and other electronic devices to perform an electric wiring function for transmission and reception of electric control signals and data signals and for supplying a power as well as an optical wiring function for transmission and reception of optical control signals and data signals.

The hybrid module 1 has packaged therein electric components such as first and second LSIs 4A and 4B or a semiconductor element 4C, which operates in conjunction with each other, and optical components such as an optical element 4D etc. Each of the first and second LSIs 4A and 4B is a multi-pin LSI designed for a higher-speed operation and larger capacity, which will not be described in detail herein. Th semiconductor element 4C is, for example, a semiconductor memory, semiconductor device or any other electronic component. The optical element 4D is, for example, a light-emitting element, such as semiconductor laser or light-emitting diode, controlled by the first LSI 4A and second LSI 4B or semiconductor element 4C to emit an optical signal or a light-receiving element such as photodiode. It should be noted that the optical element 4D may of course a composite optical element having both a light-emitting function and light-receiving function.

Note that the above components packaged in the hybrid module will generically be referred to as “components 4” hereunder except where they should be referred to individually. In the hybrid module 1, the components 4 are inserted in first to fourth component mounting concavities 7A to 7D (will be referred to as “component mounting concavities 7” hereunder except where they should be referred to individually) formed in the silicon substrate 3, and fixed by first to fourth adhesive resin layers 8A to 8D (will be referred to as “adhesive resin layers 8” hereunder except where they should be referred to individually). In the hybrid module 1, the silicon substrate 3 is used as a base material and each of the components 4 is buried in the silicon substrate 3. For explaining the hybrid module 1, the four components 4 of different types are referred to here as typical ones but a predetermined number of each of these components may be packaged in the hybrid module 1.

The components 4 have formed on first main sides 9A to 9D thereof (will be referred to as “input/output-formed sides 9” hereunder except where they should be referred to individually) input/output pads 10A to 10D (will be referred to as “input/output pads 10” hereunder except where they should be explained individually and will not be described in detail) to have the input/output-formed sides. Since the components 4 are different in type from each other as having been described above, so they are different in size and specification from each other. The components 4 have second main sides 11A to 11D opposite to the input/output-formed sides 9, and they are to be inserted first at these second main sides 11A to 11D into the component mounting concavities 7, respectively. It should be noted that the optical element 4D has provided on the input/output-formed side 9D thereof an optical input/output 12 to emit or receive an optical signal along with an input/output pad 10D.

In the silicon substrate 3, the component mounting concavities 7 are formed open to a main side 3A thereof, and they are formed equal in shape to each other to have a depth and opening size large enough to insert the component 4 whose size is largest (first LSI 4A and second LSI 4B, for example). In the silicon substrate 3, each of the component mounting concavities 7 is formed to have, on the inner wall thereof, a predetermined layer corresponding to the type of the component 4 to be inserted.

More particularly, in the silicon substrate 3, the first component mounting concavity 7A in which, for example, the first LSI 4A that is to be connected at its perimeter to the ground is to be inserted has a first conductive layer 13A formed on the inner wall thereof. In the silicon substrate 3, a first adhesive resin layer 8A is formed in the first component mounting concavity 7A to fix the first LSI 4A.

In the silicon substrate 3, the second component mounting concavity 7B in which, for example, the second LSI 4B whose perimeter provides the connection of a wiring layer 5 to the ground is to be inserted has an insulating layer (second insulating layer) 14B formed over the inner wall thereof, and a second conductive layer 13B formed on the second insulating layer 14B. In the silicon substrate 3, the second conductive layer 13B kept insulated by the second insulating layer 14B is to connect to the wiring layer 5 on the main side 3A through the opening edge of the second component mounting concavity 7B. In the silicon substrate 3, a second adhesive resin layer 8B is formed in the second component mounting concavity 7B to fix the second LSI 4B.

In the silicon substrate 3, the third and fourth component mounting concavities 7C and 7D in which a semiconductor element 4C and optical element 4D whose perimeters are to be kept insulated because they are electrically conductive are to be inserted have a third and fourth insulating layers 14C and 14D formed over their inner walls, respectively. In the silicon substrate 3, a third and fourth adhesive resin layers 8C and 8D are formed from a nonconductive adhesive material in the third and fourth component mounting concavities 7C and 7D, respectively, to fix the semiconductor element 4C and optical element 4D, respectively.

The hybrid module 1 is produced by burying the components 4 in the component mounting concavities 7, respectively, with their input/output-formed sides 9 being laid generally flush with the main side 3A of the silicon substrate 3 as shown in FIG. 1 according to the process which will be explained later. In the hybrid module 1, the components 4 are mounted being buried in the silicon substrate 3 with their input/output-formed sides 9 being exposed to outside through the openings of the component mounting concavities 7 and with their perimeters except for at least the input/output-formed sides 9 being fixed by the adhesive resin layer 8.

In the hybrid module 1, the wiring layer 5 is formed over the main side 3A of the silicon substrate 3 to cover the components 4. The wiring layer 5 includes an insulative resin layer 15, first to third wiring patterns 16A to 16C (will be referred to as “wiring patterns 16” hereunder except where they should be referred to individually) formed on the insulative resin layer 15, multiple viaholes including first and second, 17A and 17B (will be referred to as “viaholes 17” hereunder except where they should be referred to individually) for appropriate connection of the wiring patterns 16 to each other or multiple connecting pads 18 provided on an uppermost third wiring pattern 16C, etc. In the wiring layer 5, each of the wiring patterns 16 is formed from a copper wire as will be described later.

In the wiring layer 5, part of the insulative resin layer 15 is also filled in the component mounting concavities 7 to hold the perimeters of the components 4. The insulative resin layer 15 is formed by molding a transparent insulative resin to form an optical signal transmission channel to the optical element 4D. Therefore, the wiring layer 5 has a portion thereof opposite to the input/output-formed side 9D of the optical element 4D to form an optical transmission channel 15A in such a manner as not to form the wiring patterns 16 all along the thickness of, and in, the insulative resin layer 15. The wiring layer 5 thus forms the optical transmission channel 15A in part of the insulative resin layer 15 so that an optical signal emitted from the optical input/output 12 of the optical element 4D will be transmitted through the optical transmission channel 15A and goes out of a surface 5A of the wiring layer 5 as indicated with an arrow in FIG. 1.

Also, the wiring layer 5 transmits the optical signal incident upon the surface 5A through the optical transmission channel 15A for incidence upon the optical input/output 12 of the optical element 4D. It should be noted that although the hybrid module 1 has the wiring layer 5 whose part is formed as the optical transmission channel 15A, the wiring layer 5 may have provided therein opposite to the optical input/output 12 of the optical element 4D a optical waveguide including a optical waveguide member as a core formed from a transparent resin and a cladding material sheathing the optical waveguide member.

The first wiring pattern 16A is appropriately formed on the main side 3A of the silicon substrate 3 in the same process as that for forming the aforementioned conductive layers 13 in the component mounting concavities 7. The second wiring pattern 16B is appropriately formed in the insulative resin layer 15 and interlayer-connected to the first wiring pattern 16A via the multiple first viaholes 17A to provide an electrical connection between the components 4, The third wiring pattern 16C is formed on the uppermost layer (surface) of the insulative resin layer 15 and interlayer-connected to the second wiring pattern 16B via the multiple second viaholes 17B.

The wiring layer 5 has multiple connecting pads 18 formed on the third wiring pattern 16C. The connecting pads 18 are formed to a predetermined height by plating gold or the like on a predetermined land of the third wiring pattern 16C. Each of the connecting pads 18 is used as a connector when the hybrid module 1 is mounted on the base substrate 6 to provide the hybrid circuit device 2 as will be described in detail later. The connecting pads 18 are designed appropriately depending upon the method of mounting the hybrid module 1 to a multilayer wiring board 20, which will further be described later, of the base substrate 6, and they may be, for example, a solder ball or other metallic ball provided on the pad of the third wiring pattern 16C.

In the hybrid module 1, the components 4 are electrically connected with the wiring patterns 16 of the wiring layer 5 to each other as having been described above. In the hybrid module 1, the optical element 4D is supplied with a power through the wiring layer 5, and converts an electrical signal output from the first and second LSIs 4A and 4B into an optical signal or converts an optical signal into an electrical signal and supplies it to the first and second LSIs 4A and 4B.

In the hybrid module 1, the components 4 are inserted and buried into the component mounting concavities 7 formed in the above-mentioned silicon substrate 3 with their respective input/output-formed sides 9 being generally flush with the main side 3A. Therefore, the hybrid module 1 will be smaller and thinner and have more functions and higher functionality owing to a higher density of packaging. In the hybrid module 1, since the silicon substrate 3 that will incur little change in dimensions and shape due to heat or the like is used as the base substrate and has the components 4 buried therein, the components 4 can be mounted being positioned with a high accuracy and disconnection or the like between the components 4 and wiring layer 5 be prevented. Since the silicon substrate 3 having a relatively large area functions as the ground for the components 4 and wiring layer 5 and also serves as a good heat radiator, the hybrid module 1 can operate stably and is improved in reliability.

As shown in FIG. 2, the hybrid circuit device 2 includes two hybrid modules 1A and 2A each constructed as above. The hybrid modules 2A and 2B are mounted along with any other electronic component 19 on the base substrate 6 with the uppermost layer 5A of the wiring layer 5 being in contact with the base substrate 6 as shown in FIG. 2 and connected to a base wiring layer of the base substrate 6 to form the hybrid circuit device 2. Although the hybrid circuit device 2 includes the two hybrid modules 1A and 1B mounted on the base substrate 6 as shown in FIG. 2, but the hybrid circuit device 2 may include a single hybrid module 1 or more than two mounted on the base substrate 6.

In the hybrid circuit device 2, the base substrate 6 includes an optical waveguide member 21 mounted on the multilayer wiring board 20 formed with the well-known multilayer wiring board technology. The multilayer wiring board 20 is formed by forming a multilayer wiring pattern included in the base wiring layer and including an organic substrate of glass epoxy or the like and inorganic substrate of ceramic or the like as base materials with an insulating layer laid between the base materials, and making interlayer connection of the wiring pattern layers to each other through appropriately formed viaholes. In the multilayer wiring board 20, each wiring pattern layer connects the hybrid modules 1A and 1B and other electronic component 19 mounted on the base substrate 6 to each other.

The multilayer wiring board 20 has formed therein a power supply pattern having an area large enough to supply a power to the hybrid module 1, which will not be described in detail herein, or a ground pattern. The multilayer wiring board 20 supplies a high-regulation power to the hybrid module 1. Also, a heat radiation pattern which is also a ground pattern, which will not be described in detail herein, may be formed in the multilayer wiring board 20. With the conductive layer 13 formed in the component mounting concavities 7A and 7B of the hybrid module 1 being connected to the heat radiation pattern with the wiring layer 5 laid between them, the multilayer wiring pattern 20 can radiate heat dissipated from the first and second LSIs 4A and 4B with a high efficiency.

The hybrid circuit device 2 includes, for example, a light-receiving element as the optical element 4D at the first hybrid module 1A, and a light-emitting element as the optical element 4D at the second hybrid module 1B. In the hybrid circuit device 2, an electrical signal is transferred between the first and second hybrid modules 1A and 1B through the wiring pattern of the multilayer wiring board 20, while an optical signal emitted from the optical element 4D at the second hybrid module 1B is received by the optical element 4D at the first hybrid module 1A.

In the multilayer wiring board 20, the wiring pattern includes a signal pattern as well as a power wiring pattern or ground pattern, etc. The multilayer wiring board 20 has formed on the second main side thereof multiple electrode pads via which the hybrid circuit device 2 is mounted on a mounting board or the like (not shown).

The multilayer wiring board 20 has an insulating protective layer 22 formed on the main side thereof on which the hybrid module 1 is mounted. The multilayer wiring board 20 has multiple lands formed thereon opposite to openings formed in the insulating protective layer 22 correspondingly to the connecting pads 18 of the hybrid module 1, and bumps formed on the lands. The multilayer wiring board 20 has mounted thereon the hybrid module 1 with the bumps being connected to the corresponding connecting pads 18. It should be noted that the insulating protective layer 22 is formed from a light-guiding insulative resin because it has to optically connect the optical element 4D of the hybrid module 1 to the optical waveguide member 21 as will be described later.

The base substrate 6 has an optical waveguide member 21 provided in the insulating layer of the multilayer wiring board 20. The optical waveguide member 21 is positioned opposite to both the hybrid modules 1A and 1B mounted side by side. The optical waveguide member 21 is formed by molding a light guiding resin such as polyimide resin, epoxy resin, acrylic resin, polyolefin resin or rubber resin, and coated with a clad layer 23 different in refractive index from the optical waveguide member 21. The optical waveguide member 21 provides a light-tight optical waveguide through which an optical signal is transmitted being sealed two- or three-dimensionally.

An optical signal is incident upon one end of the optical waveguide member 21 and goes out at the other end, which will not be described in detail herein. Each of the ends is cut at an angle of 45 deg. to provide a mirror surface. Thus, the optical signal transmitted in the optical waveguide member 21 is to have its light path turned through 90 deg. With the hybrid modules 1A and 1B being mounted on the base substrate 6, the optical waveguide member 21 is opposite at each end thereof to a corresponding optical transmission channel 15A, in other words, to a corresponding optical input/output 12 of the optical element 4D. Therefore, an optical signal emitted from the optical element (light-emitting element) 4D of the hybrid module 1A, for example, is incident upon one end of the optical waveguide member 21, transmitted in the optical waveguide member 21, and incident upon the optical element (light-receiving element) 4D at the hybrid module 1B through the optical transmission channel 15A.

The hybrid circuit device 2 constructed as above has mounted on the base substrate 6 the hybrid modules 1 designed small, thin, capable of a high-density packaging for many functions and a high functionality and operable accurately and stably. The hybrid circuit device 2 is improved in reliability because the hybrid modules 1 are prevented from being deformed by heat or the like and their connections with the base substrate 6 are prevented from being broken and cracked. In the hybrid circuit device 2, a power supply and ground having a sufficient area are provided in the multilayer wiring board 20 of the base substrate 6 to supply the hybrid modules 1 with a high-regulation power.

The parasitic capacitance of each of the hybrid modules 1A and 1B mounted on the hybrid circuit device 2 is lowered because the electronic components such as the first and second LSIs 4A and 4B, semiconductor element 4C or the like are the optical element 4D are electrically connected over a shortest distance to each other with a high accuracy via the wiring layer 5, and an optical signal is transmitted efficiently between the hybrid modules 1A and 1B via the optical element 4D and optical waveguide member 21. Therefore, since signal transmission can be made optically between, for example, the hybrid modules 1A and 1B, the hybrid circuit device 2 can operate at a higher speed and with a larger capacity.

The process of producing the aforementioned hybrid module 1 includes a component mounting concavity forming step in which the component mounting concavities 7 are formed in the silicon substrate 3 equivalent to a silicon substrate used in the general semiconductor producing process, a component mounting step in which the components 4 are mounted on the silicon substrate 3, and a wiring layer forming step in which the wiring layer 5 is applied to over the main side 3A of the silicon substrate 3 to cover the components 4. In the component mounting concavity forming step, a plurality of component mounting concavities 7 is formed by etching, for example, in the main side 3A of the silicon substrate 3.

In the component mounting concavity forming step, the component mounting concavities 7 open to the main side 3A in the silicon substrate 3 through a silicon etching film forming, etching and silicon etching film removal in this order. In the silicon etching film forming step, a silicon etching film 30 of, for example, silicon dioxide (SiO₂), silicon nitride (SiₓN_{y}) or the like is formed with the main side 3A of the silicon substrate 3 being masked at portions thereof corresponding to the component mounting concavities 7. It should be noted that in the silicon etching film forming step, a silicon dioxide film is formed by thermal oxidation on the silicon substrate 3 or a silicon dioxide film or silicon nitride film is formed by chemical vapor deposition (CVD), sputtering or the like on the silicon substrate 3.

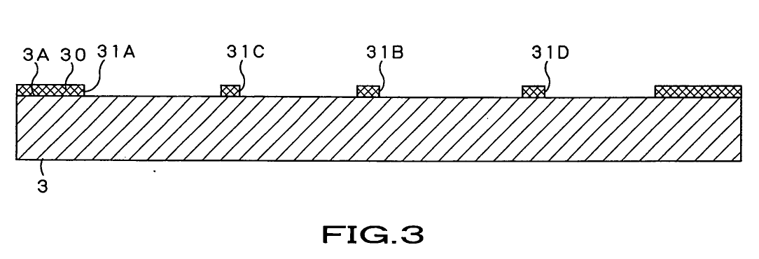

Over the main side 3A of the silicon substrate 3, there is formed, with the above-mentioned method, a silicon etching film 30 having formed therein openings 31A to 31D corresponding to the portions where the component mounting concavities 7 are to be formed as shown in FIG. 3. It should be noted that after formed over the main side 3A of the silicon substrate 3, the silicon etching film 30 may have the openings 31 formed correspondingly to the portions where the component mounting concavities 7 are formed.

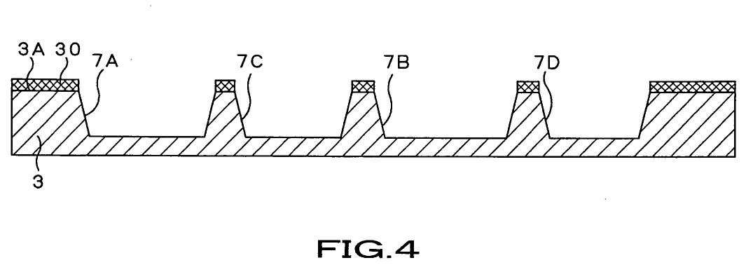

In the etching step, the component mounting concavities 7 equal in shape to each other are collectively formed as shown in FIG. 4 by etching the portions of the silicon substrate 3, exposed through the openings 31 in the silicon etching film 30. In the etching step, if the silicon substrate 3 is of, for example, 100 in direction of alignment, it is subjected to anisotropic etching with an alkaline etching solution of f KOH, TMAH or the like. In the etching step, there is formed the component mounting concavities 7 having a depth equal to about a half of the thickness of the silicon substrate 3. It should be noted that in case the silicon substrate 3 is other than “100” in direction of alignment, the component mounting concavities 7 may be formed by isotropic etching or dry etching of the silicon substrate 3.

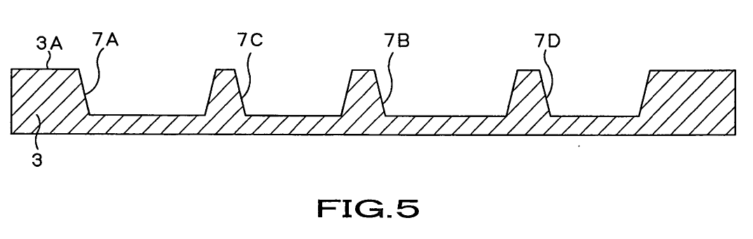

In the silicon etching form removing step, the silicon etching film 30 is removed from on the main side 3A of the silicon substrate 3 as shown in FIG. 5 by immersing the silicon substrate 3 in an appropriate solvent or by dry etching of the silicon substrate 3. In the silicon substrate 3, there are formed the component mounting concavities 7A to 7D equal in shape to each other and open to the main side 3A as shown in FIG. 5.

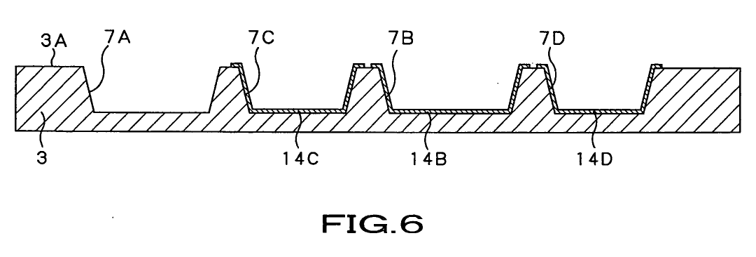

The process of producing the hybrid module 1 includes an insulating layer forming step, conductive layer forming step and adhesive resin filling step, conducted to the aforementioned component mounting concavities 7 in the silicon substrate 3. In the insulating layer forming step, an insulating layer 14 is formed on the inner wall of each of the component mounting concavities 7B to 7D in which there are to be inserted the second LSI 4B, semiconductor element 4C and optical element 4D that have to be kept insulated from the silicon substrate 3 as mentioned above. In the insulating layer forming step, the insulating layers 14 are selectively formed from, for example, an insulative resin such as epoxy resin or polyimide resin on the inner walls of the component mounting concavities 7B to 7D with portions other than those where the insulating layers 14 are to be formed being masked appropriately. The insulating layer 14 is formed on the silicon substrate 3 to extend over the bottom and inner wall of each of the component mounting concavities 7B to 7D to the main side 3A as shown in FIG. 6.

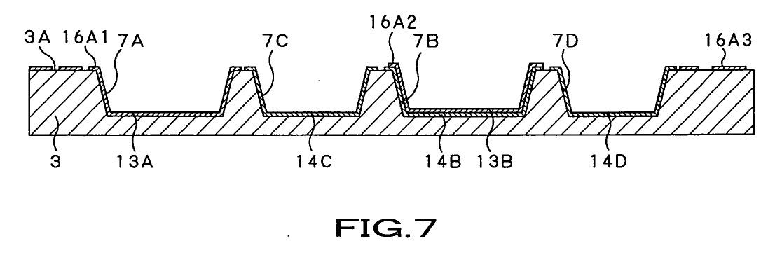

In the conductive layer forming step, the conductive layer 13 is formed on each of the component mounting concavities 7A and 7B in which there are to be inserted the first and second LSI 4A and 4B which are connected at their perimeter to the ground as mentioned above. In the conductive layer forming step, the conductive layer 13 is formed by forming a metal layer over the silicon substrate 3 including the component mounting concavities 7, plating the metal layer with copper with portions of the metal layer other than those which are to be so plated being masked with a plating resist layer, and then removing unnecessary portions of the plating resist layer and metal layer. The conductive layer 13 is patterned on the inner walls and opening edges of the component mounting concavities 7A and 7B as shown in FIG. 7.

Note that in the conductive layer forming step, the first wiring pattern 16A forming the wiring layer 5 is also formed on the main side 3A of the above silicon substrate 3. As shown in FIG. 7, the first wiring pattern 16A includes a conductive portion 16A1 formed in the component mounting concavity 7A to extend from the opening edge to the main side 6A, a conductive portion 16A2 formed on the first insulating layer 14B of the component mounting concavity 7B to extend from the opening edge to the main side 3A or conductive portion 16A3 formed being appropriately patterned on the main side 3A, and the like.

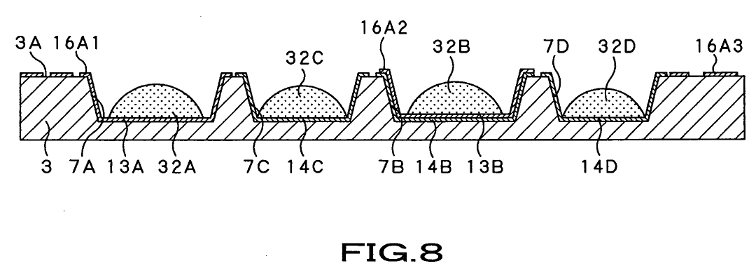

In the adhesive resin filling step, an adhesive resin 32 is filled in each of the component mounting concavities 7 to form an adhesive resin layer 8 which fixes the component 4. The component mounting concavities 7 are equal in shape to each other as mentioned above and the components 4 different in outside dimensions from each other are to be inserted and fixed by the adhesive resin layer 8 in the component mounting concavities 7, respectively. In the adhesive resin filling step, a volumetric feeder such as a dispenser is used to fill a predetermined amount of the adhesive resin 32 in liquid state into each of the component mounting concavity 7 as shown in FIG. 8. In the adhesive resin filling step, the amount of filling is controlled for the adhesive resin 32 not to overflow the component mounting concavity 7 even when the component 4 is inserted into the component mounting concavity 7 as will further be described later.

In the adhesive resin filling step, the adhesive resin 32 used is, for example, a thermo-setting epoxy resin or polyimide resin generally used in the semiconductor producing process or the like. In the adhesive resin filling step, conductive adhesive resins 32A and 32B prepared by mixing a conductive material such as metal powder in the adhesive resin are filled into the component mounting concavities 7A and 7B having the conductive layer 13 formed therein as above. The adhesive resins 32A and 32B form the adhesive resin layers 8A and 8B in the component mounting concavities 7A and 7B to provide electrical continuity between the conductive layer 13A and first LSI 4A and between the conductive layer 13B and second LSI 4B.

Also in the adhesive resin filling step, non-conductive adhesive resins 32C and 32D are filled into the component mounting concavities 7C and 7D in which the semiconductor element 4C and optical element 4D kept insulated from the silicon substrate 3 as above are inserted. The non-conductive adhesive resins 32C and 32D form non-conductive adhesive resin layers 8C and 8D in the component mounting concavities 7C and 7D. It should be noted that in the adhesive resin filling step, the adhesive resin 32 is pre-heated to be tack-free in the component mounting concavity 7. Also, it should be noted that the adhesive resin 32 may be one whose curing can be promoted when irradiated with ultraviolet rays, for example. Moreover, of the adhesive resins 32, the conductive adhesive resins 32A and 32B and the non-conductive adhesive resins 32C and 32D may be different in composition from each other.

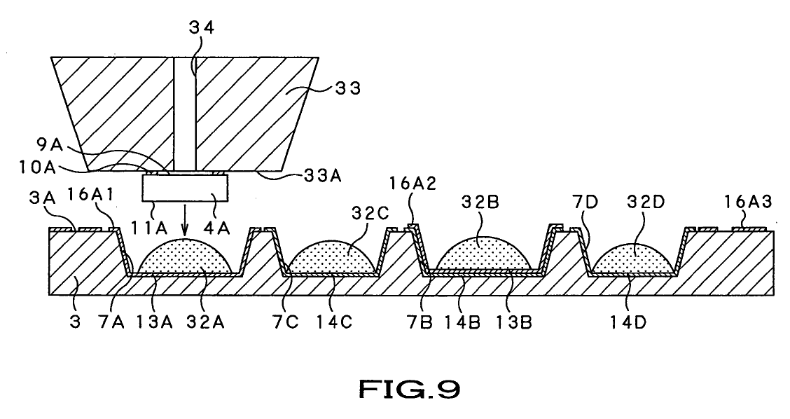

In the process of producing the hybrid module 1, for example, a vacuum type mounting apparatus is used to mount the components 4 onto the silicon substrate 3 whose component mounting concavities 7 are filled with the adhesive resins 32 as above. The component mounting step further includes a component inserting step in which the components 4 are inserted into the component mounting concavities 7, respectively, a component pressing/holding step in which each component 4 is held being pressed for its input/output-formed side 9 to be generally flush with the main side 3A of the silicon substrate 3, and a component fixing step in which the component 4 is buried in the silicon substrate 3 by curing the adhesive resin 32 with the component 4 being held being pressed to form the adhesive resin layer 8 in each component mounting concavity 7 and thus fixing the component 4 by the adhesive resin layer 8. The component mounting step will be described in detail below concerning the first LSI 4A by way of example with reference to FIGS. 9 to 11.

In the component mounting step, the first LSI 4A is sucked and caught at its input/output-formed side 9A thereof by a suction head 33 of a vacuum type mounting apparatus as shown in FIG. 9. The suction head 33 has a suction end face 33A in which a suction orifice 34 is formed as shown in FIG. 9. The suction end face 33A is formed to be flat and larger in diameter than the opening in the component mounting concavity 7A. Sucking the input/output-formed side 9A to the suction end face 33A to hold the first LSI 4A, the suction head 33 inserts the first LSI 4A first at the second main side 11A of the latter opposite to the input/output-formed side 9A into the predetermined component mounting concavity 7A through the opening of the latter as indicated with an arrow in FIG. 9.

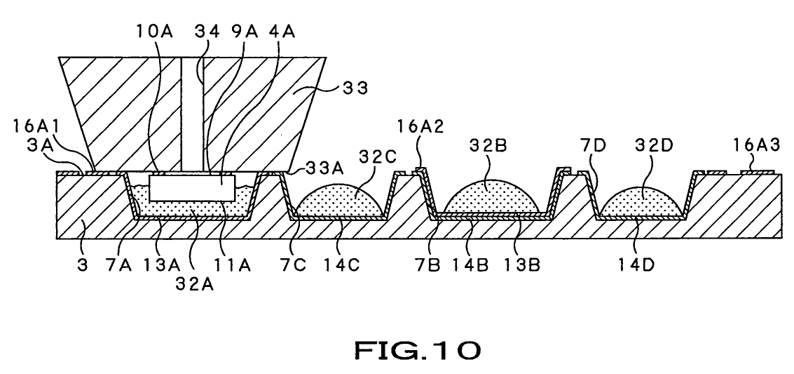

In the component mounting step, as the suction head 33 falls toward the silicon substrate 3, the first LSI 4A will thrust away the tack-free adhesive resin 32A in the component mounting concavity 7A and the adhesive resin 32A gradually move around the perimeter of the first LSI 4A. In the component pressing/holding step, the suction end face 33A abuts the opening edge of the component mounting concavity 7A as shown in FIG. 10, and thus the suction head 33 will be stopped from falling and held there. Therefore, as the suction head 33 abuts, at its suction end face 33A, the main side 3A of the silicon substrate 3, the first SLI 4A is inserted into the component mounting concavity 7A with its input/output-formed side 9A being generally flush with the main side 3A of the silicon substrate 3.

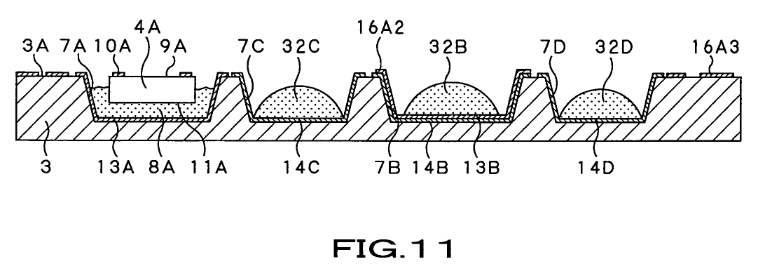

In the component fixing step, the adhesive resin 32A is cured by heating while the first LSI 4A is being held pressed by the suction head 33 in the component mounting concavity 7A. In the component fixing step, the adhesive resin 32A is cured by heating the suction head 33 or the silicon substrate 3, for example. The adhesive resin 32A moved around the perimeter of the first LSI 4A is thus cured to form the adhesive resin layer 8A by which the first LSI 4A will be fixed in the component mounting concavity 7A. The first LSI 4A is buried in the component mounting concavity 7A with its input/output-formed side 9A being generally flush with the main side 3A as shown in FIG. 11, and thus it is mounted on the silicon substrate 3.

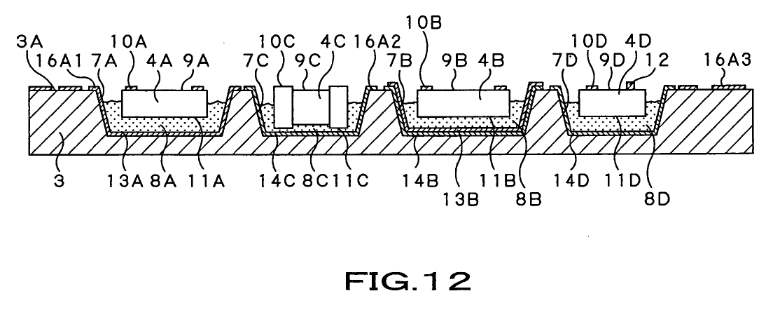

In the process of producing the hybrid module 1, a similar step to the aforementioned step of mounting the first LSI 4A is effected to bury each of the other components 4 in a corresponding one of the component mounting concavities 7. Thus, the components 4 are mounted on the silicon substrate 3. Namely, being buried in the component mounting concavities 7, respectively, with their input/output-formed sides 9 being generally flush with the main side 3A as shown in FIG. 12, the components 4 are mounted on the silicon substrate 3. It should be noted that although the components 4 are inserted one by one into the component mounting concavities 7 and fixed there in the aforementioned component mounting step, the components 4 may be sucked and caught together by the suction head 33 and then subjected to the pressing/holding step and fixing step for fixation by the adhesive resin layers 8 in the component mounting cavities 7, respectively.

The process of producing the hybrid module 1 includes a wiring layer forming step in which the wiring layer 5 including the insulative resin layer 15, wiring patterns 16 and viaholes 17 is formed on the main side 3A of the silicon substrate 3 having the components 4 fixed in the component mounting concavities 7 thereof. It should be noted that in the wiring layer 15, the wiring patterns 16 include the first to third wiring patterns 16A to 16C and the first wiring pattern 16A is formed along with the conductive layer 13 on the main side 3A of the silicon substrate 3 in the aforementioned conductive layer forming step.

The wiring layer forming step further includes a first insulative resin layer forming step in which a first insulative resin layer 35 is formed on the main side 3A of the silicon substrate 3 having the first wiring pattern 16A is formed, and a first viahole forming step in which multiple first viaholes 36 are formed in the first insulative resin layer 35. Also, the wiring layer forming step further includes a second wiring pattern forming step in which the second wiring pattern 16B is formed on the first insulative resin layer 35, and a second insulative resin layer forming step in which a second insulative resin layer 37 is formed over the second wiring pattern 16B.

The wiring layer forming step further includes a second viahole forming step in which multiple second viaholes 38 are formed in the second insulative resin layer 37, and a third wiring pattern forming step in which the third wiring pattern 16C is formed. In the wiring layer forming step, the above steps may be repeated to form a wiring layer having more layers. The wiring layer forming step further includes a connecting pad forming step in which the connecting pads 18 are formed on the third wiring pattern 16C.

In the first insulative resin layer forming step, a photosensitive light-guiding insulative resin such as epoxy resin, polyimide resin, acrylic resin, polyolefin resin or rubber resin is used to form the first insulative resin layer 35 over the main side 3A of the silicon substrate 3 since part of the insulative resin layer 15 forms the optical transmission channel 15A as above. In the first insulative resin layer forming step, a light-guiding benzocyclobutene resin having an excellent high-frequency characteristic may be used as the insulative resin.

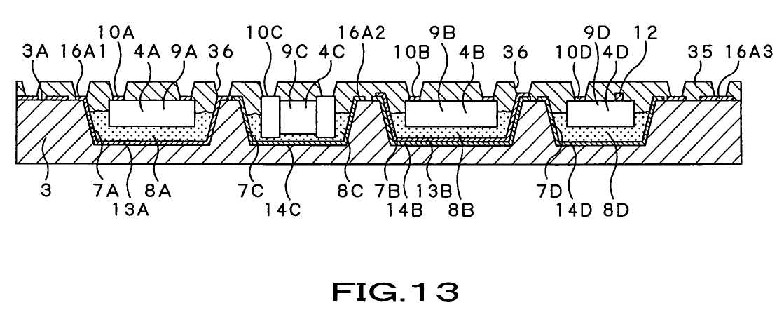

In the first insulative resin layer forming step, the first insulating layer 35 is formed by applying the aforementioned insulative resin to a uniform thickness by spin coating or dipping because the main side 3A is generally flush with the input/output-formed sides 9 of the components 4. The insulative resin should be applied to flow into the component mounting concavity 7 as well to wrap the perimeter of the component 4 as shown in FIG. 13. The insulative resin is applied to a predetermined thickness large enough to cover the component 4 and cured by heating or otherwise processing to form the first insulative resin layer 35 as shown in FIG. 13.

In the first viahole forming step, multiple first viaholes 36 are formed in the first insulative resin layer 35. The input/output pads 10 of the components 4 and pads of the first wiring pattern 16A are exposed to outside through the first viaholes 36. In the first viahole forming step, the first insulative resin layer 35 is exposed to light and developed with portions thereof corresponding to the first viaholes 36 being masked, and the insulative resin at the masked portions is removed to form the first viahole 36 through the first insulative resin layer 35 as shown in FIG. 13.

Note that in case the first insulative resin layer 35 is formed from non-photosensitive insulative resin, the first viaholes 36 are formed by dry etching with laser irradiation or the like in the first viahole forming step. Also, in the first viahole forming step, each of the first viaholes 36 is desmeared, plated with, for example, electroless copper to make the inner wall thereof electrically conductive, filled with a conductive paste and then lidded.

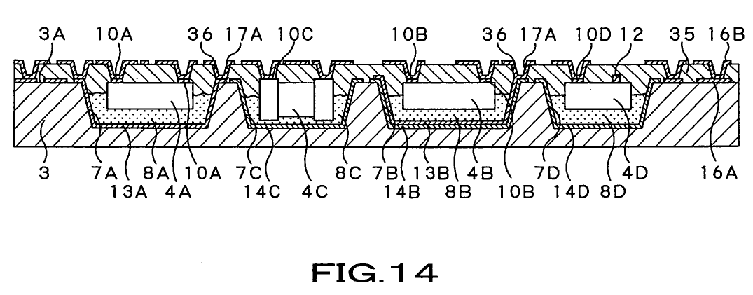

In the second wiring pattern forming step, there is formed the second wiring pattern 16B that connects the components 4 to each other and to the base substrate 6 to transfer an electrical signal, supply a power or provide a connection to the ground. The second wiring pattern forming step will not be described in detail herein. In this step, a patterning with a plating resist is made on the first insulative resin layer 35, the latter is plated with electroless copper or processed otherwise to form a copper plating layer, and the plating resist is removed from portions where it is not required, to thereby provide the second wiring pattern 16B formed from a predetermined copper wiring pattern shown in FIG. 14. It should be noted that in the second wiring pattern forming step, an appropriate pattern design is used for the second wiring pattern 16B and first viaholes 36 not to be formed on portions corresponding to the optical input/output 12 of the optical element 4D as above.

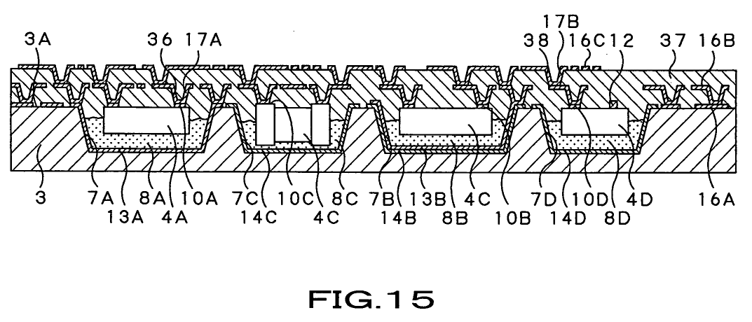

In the second insulative resin layer forming step similar to the aforementioned first insulative resin layer forming step, a second insulative resin layer 37 is formed to a uniform thickness over the first insulative resin layer 35 having the second wiring pattern 16B formed thereon as shown in FIG. 15. Also in the second insulative resin layer forming step, the same insulative resin as that forming the first insulative resin layer 35, it is applied to over the first insulative resin layer 35 to a uniform thickness by spin coating or the like, and then cured by heating or the like to form the second insulative resin layer 37.

In the second viahole forming step, there are formed in the second insulative resin layer 37 multiple second viaholes 38 through which appropriate pads formed on the second wiring pattern 16B, which will not be described in detail herein, are exposed to outside. In the second viahole forming step similar to the first viahole forming step, portions of the second insulative resin layer 37, corresponding to the second viaholes 38, are masked, and the second insulative resin layer 37 is exposed to light and developed to remove the insulative resin from the masked portions to form the multiple second viaholes 38 through the second insulative resin layer 37 as shown in FIG. 15.

Note that also in the second viahole forming step, in case the second insulative resin layer 37 has been formed from a non-photosensitive insulative resin, the second viaholes 38 are formed by the dry etching with laser irradiation or the like. Also in the second viahole forming step, each of the second viaholes 38 is desmeared, plated with, for example, electroless copper to make the inner wall thereof electrically conductive, filled with a conductive paste, and further lidded.

In the third wiring pattern forming step similar to the aforementioned second wiring pattern forming step, there is formed on the second insulative resin layer 37 the third wiring pattern 16C to be connected to the second wiring pattern 16B via the viaholes 17 and having lands or the like forming the connecting pads 18. The third wiring pattern forming step will not be described in detail herein. Also in this step, a patterning with a plating resist is made on the second insulative resin layer 37, the latter is plated with electroless copper or processed otherwise to form a copper plating layer, and the plating resist is removed from portions where it is not required, to thereby provide the third wiring pattern 16C formed from a predetermined copper wiring pattern shown in FIG. 15.

In the connecting pad forming step, there are formed the multiple connecting pads 18 used to mount the hybrid module 1 on the multilayer wiring board 20 of the base substrate 5 as above. The connecting pad forming step will not be described in detail herein. In this connecting pad forming step, the lands formed on the third wiring pattern 16C are plated with, for example, Au or Sn to form the connecting pads 18 having a predetermined thickness as shown in FIG. 1 to produce the hybrid module 1.

In the aforementioned hybrid module 1, the single light-emitting element 4D mounted is optically connected to an external device or the like to transfer an optical signal. However, the present invention is not limited to this configuration of the hybrid module 1.

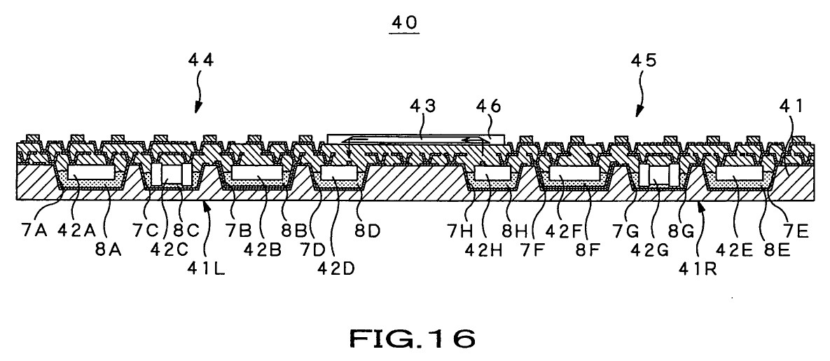

FIG. 16 is a sectional view of the second embodiment of the hybrid module according to the present invention. The hybrid module is generally indicated with a reference numeral 40. This hybrid module 40 is similar in basic configuration to the hybrid module 1 having the four components 4 mounted thereon, except that it has components 42A to 42H buried in component mounting concavities 7A to 7H formed in a silicon substrate 41 and includes an optical waveguide member 43. In the hybrid module 40, first and second optical elements 42D and 42H in pair are optically connected to each other via the optical waveguide member 43. Therefore, the same parts of the hybrid module 40 as those included in the hybrid module 1 will be indicated with the same reference numerals as having been used in the illustration and description of the hybrid module 1 will not be described any more.

The hybrid module 40 includes first and second blocks 44 and 45 laid symmetrically with respect to the center of the silicon substrate 41 and each constructed equally to the aforementioned hybrid module 1. The hybrid module 40 has four component mounting concavities 7A to 7D formed in a left area 41L of the silicon substrate 41 and in which the components 42 are inserted, buried and fixed in adhesive resin layers 8A to 8D. In the hybrid module 40, the first block 44 includes a first LSI 42A, first semiconductor element 42C, second LSI 42B and first optical element 42D disposed in the left area 41L of the silicon substrate 41 in this order and in a direction from the left end toward center of the hybrid module 40 as shown in FIG. 16.

The hybrid module 40 has four component mounting concavities 7E to 7H formed in a right area 41R of the silicon substrate 41 and in which the components 42 are inserted, buried and fixed in adhesive resin layers 8E to 8H. In the hybrid module 40, the second block 45 includes a third LSI 42E, second semiconductor element 42G, fourth LSI 42F and second optical element 42H disposed in the right area 41R in this order and in a direction from the right end toward center of the hybrid module 40.

The component mounting concavities 7A to 7H of the hybrid module 40 are collectively formed all in the same shape in the aforementioned component mounting concavity forming step. In the hybrid module 40, a conductive layer is formed on the inner wall of each of the component mounting concavities 7A and 7E in which the first and third LSIs 42A and 42E are to be buried and these LSIs 42A and 42E are fixed each by a conductive adhesive resin. In the hybrid module 40, an insulating layer and conductive layer are formed on the inner wall of each of the component mounting concavities 7B and 7F in which the second and fourth LSIs 42B and 42F are to be buried and these LSIs 42B and 42F are fixed each by a conductive adhesive resin.

In the hybrid module 40, an insulating layer is formed on the inner wall of each of the component mounting concavities 7C and 7G in which the first and second semiconductor elements 42C and 42G are to be buried and these first and second semiconductor elements 42C and 42G are fixed each by a non-conductive adhesive resin. In the hybrid module 40, an insulating layer is formed on the inner wall of each of the component mounting concavities 7D and 7H in which the first and second optical elements 42D and 42H are to be buried and these first and second optical elements 42D and 42H are fixed each by a non-conductive adhesive resin.

The hybrid module 40 uses a light-receiving element as the first optical element 42D and a light-emitting element as the second optical element 42H. In the hybrid module 40, the first and second optical elements 42D and 42H are disposed adjacently to each other symmetrically with respect to the center of the silicon substrate 41. In the hybrid module 40, an optical signal emitted from the second optical element 42H is transmitted through the optical waveguide member 43 and received by the first optical element 42D as indicated with an arrow in FIG. 16.

In the hybrid module 40, the optical waveguide member 43 is mounted on a surface 5A of the wiring layer 5. The optical waveguide member 43 is equivalent to the optical waveguide member 21 used in the aforementioned hybrid module 1. It is formed from a light guiding resin and coated with a clad layer 46 different in refractive index from the optical waveguide member 43 to provide a light-tight optical waveguide through which an optical signal is transmitted being sealed two- or three-dimensionally. Of the optical waveguide member 43, one end cut at an angle of 45 deg. to provide a mirror surface is laid opposite to the optical input/output 12 of the first optical element 42D via the optical transmission channel of the wiring layer 5 and the other end providing a similar mirror surface is laid opposite to the optical input/output 12 of the second optical element 42H via the optical transmission channel of the wiring layer 5.

In the hybrid module 40 constructed as above, the first and second optical elements 42D and 42H and the optical waveguide member 43 form together an optical signal transmission system through which an optical signal is transferred between the first and second blocks 44 and 45. In the hybrid module 40, a data signal and control signal processed by the third and fourth LSIs 42E and 42G of the second block 45 are converted into optical signals which will be allowed to go out at the optical input/output 12 of the second optical element 42H.

In the hybrid module 40, the optical signal emitted from the second optical element 42H passes by the wiring layer 5 and is guided to the surface 5A, and is incident upon the optical waveguide member 43 from the one end via the wiring layer 5. In the hybrid module 40, the optical signal thus guided into the optical waveguide member 43 is incident upon the wiring layer 5 from the other end, and guided. In the hybrid module 40, the optical signal incident upon the wiring layer 5 is received by the optical input/output 12 of the first optical element 42D.

As above, an optical signal is transferred within the hybrid module 40 itself. Thus, the light is less lost during the transmission. Data signal or the like can be transmitted between the first and second blocks 44 and 45 efficiently, rapidly and in an increased volume. Since the hybrid module 40 has a structure in which the electrical signal processing components and optical signal processing components are provided together and connected with each other over a shortest distance, the wiring structure is shortened and thus the parasitic capacitance is also reduced.

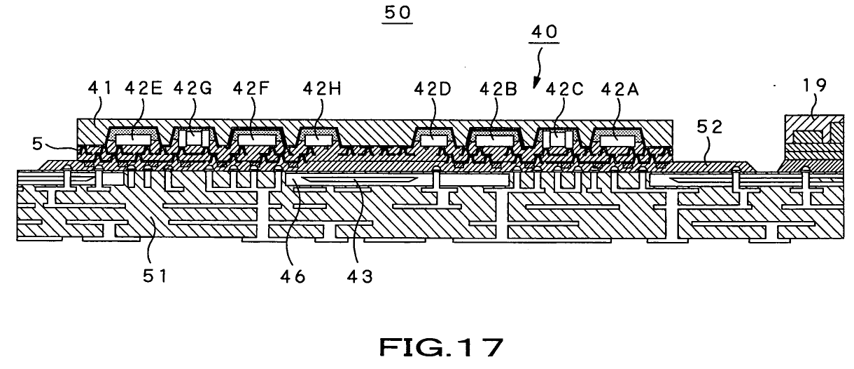

FIG. 17 is a sectional view of the second embodiment of the hybrid circuit device according to the present invention. The hybrid circuit device is generally indicated with a reference numeral 50. As shown, the hybrid circuit device 50 includes the aforementioned hybrid module 40 and other electronic components 19. The uppermost layer 5A of the wiring layer 5 being laid as a mounting surface, the hybrid module 40 and other electronic components 19 are mounted a base substrate 51 of the hybrid circuit device 50. In the hybrid circuit device 50, the base substrate 51 is formed from a multilayer wiring board produced with the general multilayer wiring board technology similarly to the multilayer wiring board 20 of the aforementioned hybrid circuit device 2. Therefore, the same elements of the hybrid circuit device 50 as those in the hybrid circuit device 2 will be indicated with the same reference numerals as those having been used in the illustration and description of the hybrid circuit device 2 and will not be described any more.

The hybrid circuit device 50 will not be described in detail. In the hybrid circuit device 50, the hybrid module 40 is mounted on the base substrate 51 with the connecting pads 18 being joined to the corresponding lands of the wiring pattern formed on the main side of the base substrate 51. In the base substrate 51 of the hybrid circuit device 50, there are formed appropriate circuits corresponding to the first and second blocks 44 and 45 of the hybrid module 40. Also in the hybrid circuit device 50, the base substrate 51 supplies a high-regulation power to the hybrid module 40 and serves as a ground and heat radiator. The hybrid circuit device 50 is to be mounted on a mounting board (not shown) via electrode pads formed on the second main side of the base substrate 51.

In the hybrid circuit device 50, an insulating protective layer 52 formed on the main side of the base substrate 51 covers and protects the connections between the wiring layer 5 of the hybrid module 40 and connecting pads 18. In the hybrid circuit device 50, the insulating protective layer 52 covers, fixes and holds an optical waveguide member 52 mounted on the wiring layer 5 of the hybrid module 40. It should be noted that although in the aforementioned hybrid module 2, the insulating protective layer 52 is formed from the light-guiding insulative resin because it has a function to optically connect the optical element 4D and optical waveguide member 21 to each other, the insulating protective layer 43 is formed from, for example, an insulative resin containing a filler because it has no such function.

The hybrid circuit device 50 constructed as above has mounted on the base substrate 51 the small, thin hybrid module 40 designed small, thin, capable of a high-density packaging for many functions and a high functionality and operable accurately and stably. The hybrid circuit device 50 is improved in reliability because the hybrid module 40 is prevented from being deformed by heat or the like and its connections with the base substrate 51 are prevented from being broken and cracked. In the hybrid circuit device 50, a power supply and ground having a sufficient area are provided in the base substrate 51 to supply the hybrid module 40 with a high-regulation power.

The hybrid circuit device 50 can operate at a high speed and with a larger capacity because it has mounted thereon the hybrid module 40 capable of processing data signal and the like at a higher speed and in a larger volume via the optical signal transmission system included therein. The hybrid circuit device 50 is highly versatile because the base substrate 51 is equivalent to the generally wiring board used in electronic devices.

In the foregoing, the present invention has been illustrated and described concerning the hybrid modules and hybrid circuit boards as the embodiments thereof, having mounted on the silicon substrate thereof the optical elements and thus capable of the electrical signal processing to transfer electric control signals and data signals and supply a power and the optical signal processing to transfer optical control signals and data signals. However, the present invention is not limited to these embodiments but is of course applicable to a hybrid module and hybrid circuit device capable of only the electrical signal processing, for example.

It should be understood by those skilled in the art that various modifications, combinations, sub-combinations and alterations may occur depending on design requirements and other factors insofar as they are within the scope the appended claims or the equivalents thereof.

What is claimed is:

1. A hybrid module comprising:
a silicon substrate having formed therein a plurality of component mounting concavities open to one of main sides of the silicon substrate;
a plurality of components inserted in the component mounting concavities, respectively, with their input/output-formed sides being exposed to outside through the openings of the component mounting concavities and buried in the silicon substrate with their perimeters except for at least their input/output-formed sides being fixed by adhesive layers formed in the component mounting concavities; and
a wiring layer formed on the main side of the silicon substrate to cover the components and which has a wiring pattern provided on an insulative resin layer included in the wiring layer and which is connected to an input/output provided on the input/output-formed side of each of the components.

2. The hybrid module according to claim 1, wherein the components are different in characteristic from each other.

3. The hybrid module according to claim 2, wherein a predetermined one of the component mounting concavities in which a component being an electric component is to be buried has formed over the inner wall thereof an insulating layer which provides an electrical insulation between the silicon substrate and component.

4. The hybrid module according to claim 3, wherein the component being an electric component and having electrical connections also on the perimeter thereof except for the input/output-formed side thereof is buried in and fixed by an electrically conductive insulative resin layer filled and cured in the predetermined component mounting concavity having a conductive layer extending on the insulating layer over the main side of the silicon substrate via the opening edge.

5. The hybrid module according to claim 2, wherein
the predetermined component mounting concavity has formed over the inner wall thereof an insulating layer which provides an electrical insulation between the silicon substrate and component and has also formed on the insulating layer a conductive layer extending over the main side of the silicon substrate via the opening edge, and
the conductive layer is connected to a heat radiation pattern formed on the wiring layer.

6. The hybrid module according to claim 2, wherein at least one of the components is an optical element including a light-emitting element and light-receiving element.

7. The hybrid module according to claim 6, wherein an optical transmission channel is formed on the main side of the silicon substrate or in the wiring layer and on the main side of the wiring layer oppositely to an input/output end of the optical element.

8. The hybrid module according to claim 7, wherein the optical transmission channel is formed from a light-transmissive polymeric material.

9. The hybrid module according to claim 8, wherein the optical transmission channel is a light waveguide to transmit an optical signal incident upon one end thereof in a sealed state to the other end, one of the ends being laid opposite to the optical element.

10. The hybrid module according to claim 6, wherein the insulating layer of the wiring layer is formed from a light-transmissive insulative resin to provide the optical transmission channel of the optical element.

11. The hybrid module according to claim 1, wherein the wiring layer includes a copper wiring pattern formed on the insulating layer by patterning a copper-plate layer, and viaholes and multiple external-connection pads for connecting the copper wiring pattern and input/output of each component to each other.

12. A method of producing a hybrid module, comprising the steps of:
forming, in a silicon substrate, a plurality of component mounting concavities open to one of main sides of the silicon substrate;
mounting components in a buried state into the component mounting concavities, respectively; and
forming a wiring layer over the main side of the silicon substrate to cover the components,
the component mounting step further including the steps of:
filling a predetermined amount of tack-free adhesive resin into each of the component mounting concavities;
inserting the plurality of components into corresponding component mounting concavities with their respective input/output-formed sides being exposed to outside through the openings of the component mounting concavities;
pressing and holding the components for their input/output-formed sides to be laid generally flush with each other; and
fixing each of the components by curing the adhesive resin with the component being held pressed to form an adhesive resin layer in the component mounting concavity and burying the component in the silicone substrate with the component being fixed by the adhesive resin layer,
the wiring layer forming step further including the steps of:
forming an insulating layer over the main side of the silicon substrate and the input/output-formed sides of the components, which are laid generally flush with main side; and
forming, on the insulating layer, a wiring pattern for connection to an input/output formed on the input/output-formed side of each component.

13. The method according to claim 12, wherein in the component mounting step, the components different in characteristic from each other are mounted being buried in the component mounting concavities, respectively.

14. The method according to claim 13, wherein before the adhesive resin filling step of the component mounting step, an insulating layer which provides an electrical insulation between the silicon substrate and component is formed on the inner wall of a predetermined one of the component mounting concavities in which a component being an electric one is to be buried.

15. The method according to claim 14, wherein
after the insulating layer forming step and before the adhesive resin filling step of the component mounting step, a conductive layer extending over the main side of the silicon substrate via the opening edge is formed on the insulating layer in a predetermined one of the component mounting concavities in which a component being an electric one and having an electrical connection also on the perimeter thereof except for the input/output-formed side, and
the tack-free adhesive resin to be filled into the component mounting concavities in the adhesive resin filling step is an electrically conductive adhesive resin.

16. The method according to claim 13, wherein in the component mounting step, as at least one of the components, an optical element including a light-emitting element and light-receiving element is mounted being buried in the component mounting concavity.

17. The method according to claim 16, wherein before or during and after the wiring layer forming step, an optical transmission channel is formed on the main side of the silicon substrate or in the wiring layer and on the main side of the wiring layer oppositely to the input/output-formed side of the optical element.

18. The method according to claim 17, wherein in the optical transmission channel forming step, the optical transmission channel is formed from a light-transmissive polymeric material.

19. The method according to claim 16, wherein in the insulating layer forming step of the wiring layer forming step, the insulating layer is formed from a light-transmissive insulative resin which forms the optical transmission channel of the optical element.

20. The method according to claim 13, wherein in the wiring pattern forming step of the wiring layer forming step, the insulating layer is copper-plated to form a copper wiring pattern, and viaholes and multiple external-connection pads are formed for connecting the copper wiring pattern and an input/output of each component to each other.

21. A hybrid circuit device comprising:
a base substrate having formed on an insulating substrate thereof a base wiring layer formed from an insulating layer and a single- or multi-layer wiring pattern; and
a hybrid module mounted on the base wiring layer of the base substrate,
the hybrid module including:
a silicon substrate having formed therein a plurality of component mounting concavities open to one of main sides of the silicon substrate;
a plurality of components inserted in the component mounting concavities with their respective sides having an input/output formed thereon being exposed to outside through the openings of the component mounting concavities, fixed at the perimeters thereof except for at least the input/output-formed sides with an adhesive resin layer formed by curing an adhesive resin filled in the component mounting concavities, and thus mounted being buried in the silicon substrate; and
a wiring layer including an insulative resin layer formed on the main side of the silicon substrate to cover the component mounting concavities and a wiring pattern to be connected to the input/output of each of the components,
the hybrid module being mounted on the base wiring layer of the base substrate via external-connection pads formed on the uppermost layer of the wiring layer formed on the main side of the silicon substrate and the input/output-formed sides of the components, which are generally flush with each other.

22. The hybrid circuit device according to claim 21, wherein the hybrid module is surface-mounted along with other surface-mounted components on the base wiring layer of the base substrate.

23. The hybrid circuit device according to claim 21, wherein the components are different in characteristic from each other.

24. The hybrid circuit device according to claim 23, wherein in the hybrid module, at least one of the components is an optical element including a light-emitting element and light-receiving element.

25. The hybrid circuit device according to claim 24, wherein an optical transmission channel is formed in the wiring layer of the base substrate to be opposite to an input/output of the optical element.
